(19) United States
(12) Patent Application Publication
(10) Pub. No.: US 2025/0326926 A1
(43) Pub. Date: Oct. 23, 2025

(54) RESIN COMPOSITION FOR MOLDING, AND ELECTRONIC COMPONENT DEVICE

(71) Applicant: RESONAC CORPORATION, Tokyo (JP)

(72) Inventors: Mika TANAKA, Minato-ku, Tokyo (JP); Takahiro HORIE, Minato-ku, Tokyo (JP); Yuma TAKEUCHI, Minato-ku, Tokyo (JP); Yuta SUKEGAWA, Minato-ku, Tokyo (JP)

(73) Assignee: RESONAC CORPORATION, Tokyo (JP)

(21) Appl. No.: 18/861,575

(22) PCT Filed: Nov. 21, 2023
(86) PCT No.: PCT/JP2023/041786

§ 371 Date: Oct. 29, 2024

(30) Foreign Application Priority Data
Nov. 22, 2022 (JP) 2022-186879

(51) Int. Cl. C08L 63/04; C08L 63/00; C09K 3/10; H01L 23/29

(52) U.S. Cl. CPC C08L 63/04; C08L 63/00; C09K 3/1012; H01L 23/295; C08L 2203/20; C08L 2205/025; C08L 2205/035; C09K 2200/0625; C09K 2200/0657; C09K 2200/0682

(57) ABSTRACT

The resin composition for molding includes: a sulfur atom-containing epoxy resin; a curing agent; a release agent; an inorganic filler; and a copolymer of a C5-30 α-olefin and at least one of maleic anhydride and a maleic anhydride derivative.

### TECHNICAL FIELD

The disclosure relates to a resin composition for molding and an electronic component device.

### RELATED ART

Conventionally, in the field of element sealing for electronic component devices such as transistors, integrated circuits (ICs), and large scale integration (LSI), resin sealing has become mainstream in terms of productivity, cost, and other factors. Epoxy resin compositions are widely used as epoxy resin molding materials for sealing. The reason is that epoxy resins excel in the balance of various properties such as electrical properties, moisture resistance, heat resistance, mechanical properties, and adhesion to insert products.

To improve the production efficiency of electronic component devices and achieve favorable continuous moldability, generally, a release agent is added to the epoxy resin composition for smooth release from the mold. As a release agent, copolymers of α-olefin and maleic anhydride (see, for example, Patent Document 1), compounds obtained by esterifying copolymers of α-olefin and maleic anhydride (see, for example, Patent Documents 2 and 3), oxidized polyolefin (see, for example, Patent Document 4), etc., have been reported. Additionally, a method for achieving favorable release properties and favorable package appearance by combining the release agent that is an oxidized polyolefin wax compound with the copolymer of α-olefin and maleic anhydride or maleic anhydride derivative (see, for example, Patent Document 5) has also been reported.
Patent Document 1: Japanese Patent Application Laid-Open Publication No. H10-036486
Patent Document 2: Japanese Patent Application Laid-Open Publication No. 2001-247748
Patent Document 3: Japanese Patent Application Laid-Open Publication No. 2003-64239
Patent Document 4: Japanese Patent Application Laid-Open Publication No. 2006-182913
Patent Document 5: Japanese Patent Application Laid-Open Publication No. 2005-255978

### SUMMARY OF INVENTION

### Technical Problem

To improve the production efficiency of electronic component devices and achieve favorable continuous molding properties, further enhancement of release properties for epoxy resin compositions is desired.

The disclosure is made in view of the above-mentioned conventional circumstances and aims to provide a resin composition for molding with excellent release properties, and an electronic component device using the same.

### Solution to Problem

The specific means for achieving the above-mentioned objective are as follows.

<1> A resin composition for molding includes a sulfur atom-containing epoxy resin; a curing agent; a release agent; an inorganic filler; and a copolymer of an α-olefin having 5 to 30 carbon atoms and at least one of maleic anhydride and a maleic anhydride derivative.

<2> In the resin composition for molding according to <1>, the sulfur atom-containing epoxy resin includes a compound represented by General Formula (B) represented as follows:

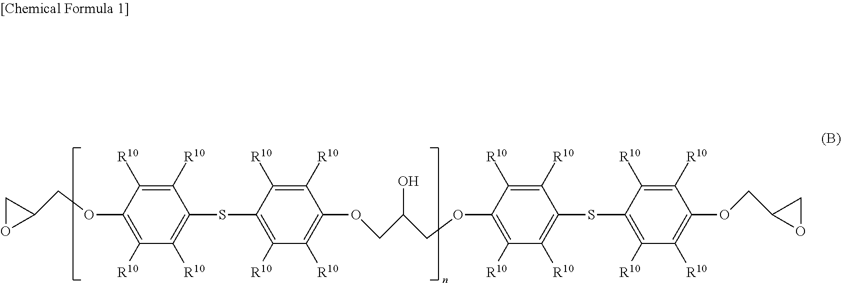

(In General Formula (B), R¹⁰ represents a hydrogen atom or a monovalent organic group having 1 to 18 carbon atoms, and respective R¹⁰ are all same or different, and n represents an average value and is a number from 0 to 10).

In the resin composition for molding according to <1> or <2>, the release agent is a polyethylene oxide.

<4> In the resin composition for molding according to <3>, the polyethylene oxide is a linear polyethylene oxide.

<5> In the resin composition for molding according to <3> or <4>, the polyethylene oxide is a branched polyethylene oxide.

<6> In the resin composition for molding according to any one of <3> to <5>, a weight average molecular weight of the polyethylene oxide is 2800 or more.

<7> In the resin composition for molding according to any one of <3> to <6>, an acid value of the polyethylene oxide is 2 mgKOH/g to 50 mgKOH/g.

<8> In the resin composition for molding according to any one of <1> to <7>, the copolymer includes a structural unit represented by General Formula (C) as follows and a structural unit represented by General Formula (D) as follows:

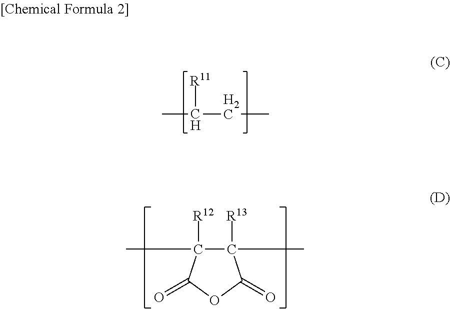

(In General Formula (C) and General Formula (D), R¹¹ represents a monovalent aliphatic hydrocarbon group having 3 to 28 carbon atoms, and R¹² and R¹³ each independently represent a hydrogen atom, an alkyl group, or an aryl group.)

<9> An electronic component device includes: a support member; an electronic component disposed on the support member; and a cured product of the resin composition for molding according to any of <1> to >8> that seals the electronic component.

### Effects of Invention

According to the disclosure, a resin composition for molding with excellent release properties, and an electronic component device using the same can be provided.

### BRIEF DESCRIPTION OF DRAWINGS

FIG. 1 is a figure showing the transition of the shear release strength for Examples 1 to 5 and Comparative Examples 1 to 3.

FIG. 2 is a figure showing the transition of the shear release strength for Example 6 and Comparative Example 4.

### DESCRIPTION OF EMBODIMENTS

The following describes in detail the embodiments of the disclosure. However, the disclosure is not limited to the following embodiments. In the following embodiments, the components (including element steps, etc.) are not essential unless specifically stated. The same applies to numerical values and their ranges, which do not limit the disclosure.

In the disclosure, the term “step” includes not only steps independent from other steps, but also steps that may not be clearly distinguishable from other steps, as long as the purpose of

the step is achieved.

In the disclosure, numerical ranges indicated using “˜” or “to” include the values before and after “˜” or “to” as the minimum and maximum values, respectively.

In the numerical ranges described stepwise in the disclosure, an upper limit or lower limit described in one numerical range may be replaced with an upper limit or lower limit value of another stepwise described numerical range. Additionally, in the numerical ranges described in the disclosure, the upper limit or lower limit of the numerical range may be replaced with a value shown in the examples.

In the disclosure, multiple types of corresponding substances may be provided in each component.

In the case where multiple types of substances corresponding to the respective components are present in the composition, the content ratio or the content of each component refers to the total content ratio or the total content of the multiple types of substances present in the composition, unless otherwise specified.

In the disclosure, multiple types of particles may be provided in the particles corresponding to each component. In the case where multiple types of particles corresponding to each component are present in the composition, unless otherwise specified, the particle size of each component means the value for the mixture of the multiple types of particles present in the composition.

### <Resin Composition for Molding>

The resin composition of the disclosure for molding includes: a sulfur atom-containing epoxy resin; a curing agent; a release agent; an inorganic filler; and a copolymer of an α-olefin having 5 to 30 carbon atoms and at least one of maleic anhydride and a maleic anhydride derivative (referred to as “specific copolymer” in the following).

The resin composition for molding of the disclosure excels in release properties. Although the reason is not clear, it is presumed to be as follows.

The specific copolymer has, within its molecule, a hydrophobic structural unit derived from an α-olefin having 5 to 30 carbon atoms and a hydrophilic structural unit derived from at least one of maleic anhydride and a maleic anhydride derivative. Therefore, by using the specific copolymer, the release agent can be favorably dispersed in the epoxy resin, and in the case where the resin composition for molding is cured to form a cured product, the release agent is easily dispersed uniformly in the cured product.

In addition, by using the sulfur atom-containing epoxy resin, the release agent tends to exude more easily to the surface of the cured product.

The release agent uniformly dispersed in the cured product tends to exude uniformly from the surface of the cured product. As a result, it becomes easier to release the cured product from the mold. Furthermore, by repetitively encapsulating electronic components with the release agent adhering to the surface of the mold after exuding from the surface of the cured product, the amount of the release agent adhering to the surface of the mold increases, making the cured product even easier to be released from the mold.

Based on the above, it is presumed that the resin composition for molding of the disclosure excels in release properties.

The following describes each component forming the resin composition for molding. The resin composition for molding of the disclosure includes a sulfur atom-containing epoxy resin as the epoxy resin, a curing agent, a release agent, an inorganic filler, and a specific copolymer, and may include other components as necessary.

### (Epoxy Resin)

The resin composition for molding of the disclosure includes a sulfur atom-containing epoxy resin as the epoxy resin. The resin composition for molding of the disclosure may also include another epoxy resin other than the sulfur atom-containing epoxy resin.

In the case where the resin composition for molding of the disclosure includes such other epoxy resin, the ratio of the sulfur atom-containing epoxy resin in the epoxy resin is preferably 5 mass % to 50 mass %, more preferably 10 mass % to 40 mass %, and even more preferably 18 mass % to 30 mass %.

The mass ratio of the epoxy resin in the entire resin composition for molding is preferably 0.5 mass % to 30 mass %, more preferably 2 mass % to 20 mass %, and even more preferably 3.5 mass % to 13 mass %, from the viewpoint of strength, flowability, heat resistance, moldability, etc.

The structure of the sulfur atom-containing epoxy resin is not particularly limited as long as the sulfur atom-containing epoxy resin contains a sulfur atom in the molecule. The sulfur atom-containing epoxy resin may include, for example, an epoxy compound having a diphenyl sulfide structure, and may include a compound represented by the following General Formula (B).

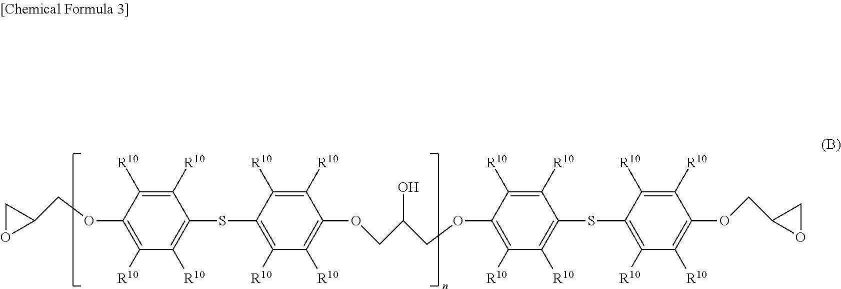

In General Formula (B), R¹⁰ represents a hydrogen atom or a monovalent organic group having 1 to 18 carbon atoms, and respective R¹⁰ may all be the same or different. n represents an average value and is a number from 0 to 10.

Examples of the monovalent organic group having 1 to 18 carbon atoms represented by R¹⁰ may include an alkyl group such as a methyl group, an ethyl group, a n-propyl group, an isopropyl group, a n-butyl group, a sec-butyl group, a tert-butyl group, a pentyl group, a hexyl group, a cyclopentyl group, a cyclohexyl group, etc.; an aryl group such as phenyl group, tolyl group, etc.; and an alkoxy group such as a methoxy group, an ethoxy group, a propoxy group, a butoxy group, etc.

In the compound represented by General Formula (B) as well, commercially available products such as YSLV-120TE (product name, manufactured by Nippon Steel Chemical & Material Co., Ltd.) can be obtained, in which, when the positions where oxygen atoms are substituted in R¹⁰ are designated as 4 and 4′ positions, the 3 and 3′ positions are tert-butyl groups, the 6 and 6′ positions are methyl groups, and the rest of R¹⁰ are hydrogen atoms.

Other epoxy resins are not particularly limited in their types as long as the epoxy resins possess epoxy groups in the molecule.

Specifically, as other epoxy resins, examples may include a novolac-type epoxy resin (phenol novolac-type epoxy resin, o-cresol novolac-type epoxy resin, etc.) obtained by epoxidizing a novolac resin produced by condensation or co-condensation under an acidic catalyst of at least one phenolic compound selected from the group consisting of a phenol compound such as phenol, cresol, xylenol, resorcinol, catechol, bisphenol A, bisphenol F, and a naphthol compound such as α-naphthol, β-naphthol, dihydroxynaphthalene, with an aliphatic aldehyde compound such as formaldehyde, acetaldehyde, propionaldehyde; a triphenylmethane-type epoxy resin obtained by epoxidizing triphenylmethane-type phenol resin produced by condensation or co-condensation under an acidic catalyst of the phenolic compound with an aromatic aldehyde compound such as benzaldehyde, salicylaldehyde; a copolymer-type epoxy resin obtained by epoxidizing a novolac resin produced by co-condensation under an acidic catalyst of the phenol compound and naphthol compound with an aldehyde compound; a diphenylmethane-type epoxy resin which is a diglycidyl ether of bisphenol A, bisphenol F, etc.; a biphenyl-type epoxy resin which is a diglycidyl ether of alkyl-substituted or unsubstituted biphenol; a stilbene-type epoxy resin which is a diglycidyl ether of a stilbene-based phenol compound; an epoxy resin which is a glycidyl ether of alcohol such as butanediol, polyethylene glycol, polypropylene glycol; a glycidyl ester-type epoxy resin which is a glycidyl ester of a polyvalent carboxylic acid compound such as phthalic acid, isophthalic acid, tetrahydrophthalic acid; a glycidylamine-type epoxy resin in which an active hydrogen bonded to a nitrogen atom of aniline, diaminodiphenylmethane, isocyanuric acid, etc. is substituted with a glycidyl group; a dicyclopentadiene-type epoxy resin obtained by epoxidizing a co-condensation resin of dicyclopentadiene and a phenol compound; an alicyclic epoxy resin 1 such as vinylcyclohexene diepoxide, 3,4-epoxycyclohexylmethyl-3,4-epoxycyclohexanecarboxylate, 2-(3,4-epoxy)cyclohexyl-5,5-spiro(3,4-epoxy)cyclohexane-m-dioxane, in which an olefin bond in the molecule is epoxidized; a paraxylylene-modified epoxy resin which is a glycidyl ether of paraxylylene-modified phenol resin; a metaxylylene-modified epoxy resin which is a glycidyl ether of metaxylylene-modified phenol resin; a terpene-modified epoxy resin which is a glycidyl ether of a terpene-modified phenol resin; a dicyclopentadiene-modified epoxy resin which is a glycidyl ether of a dicyclopentadiene-modified phenol resin; a cyclopentadiene-modified epoxy resin which is a glycidyl ether of a cyclopentadiene-modified phenol resin; a polycyclic aromatic ring-modified epoxy resin which is a glycidyl ether of a polycyclic aromatic ring-modified phenol resin; a naphthalene-type epoxy resin which is a glycidyl ether of a naphthalene ring-containing phenol resin; a halogenated phenol novolac-type epoxy resin; a hydroquinone-type epoxy resin; a trimethylolpropane-type epoxy resin; a linear aliphatic epoxy resin obtained by oxidizing an olefin bond with a peracid such as peracetic acid; an aralkyl-type epoxy resin obtained by an epoxidizing aralkyl-type phenol resin such as a phenol aralkyl resin, a naphthol aralkyl resin, a biphenyl aralkyl resin, etc. Furthermore, epoxidized products of acrylic resin may also be examples of the epoxy resin. Such other epoxy resin may be used alone or in combination of two or more types.

Such other epoxy resin preferably includes at least one of a diphenylmethane-type epoxy resin, a triphenylmethane-type epoxy resin, an o-cresol novolac-type epoxy resin, and a biphenyl aralkyl-type epoxy resin, and more preferably includes a diphenylmethane-type epoxy resin or a biphenyl aralkyl-type epoxy resin.

The epoxy equivalent (molecular weight/number of epoxy groups) of the epoxy resin is not particularly limited. From the viewpoint of balancing various properties such as moldability, reflow resistance, and electrical reliability, the epoxy equivalent of the epoxy resin is preferably 100 g/eq to 1000 g/eq. and more preferably 150 g/eq to 500 g/eq.

The epoxy equivalent of the epoxy resin is defined as a value measured according to the method conforming to JIS K 7236:2009.

In the case where the epoxy resin is solid, the softening point or the melting point of the epoxy resin is not particularly limited. From the viewpoint of moldability and reflow resistance, the softening point or the melting point of the epoxy resin is preferably 40° C. to 180° C., and from the viewpoint of handling during the preparation of the resin composition for molding, the softening point or the melting point of the epoxy resin is more preferably 50° C. to 130° C.

The melting point or the softening point of the epoxy resin is defined as a value measured by differential scanning calorimetry (DSC) or by a method (ring and ball method) conforming to JIS K 7234:1986.

### (Curing Agent)

The resin composition for molding of the disclosure includes a curing agent.

From the viewpoint of moldability and reliability, a phenol curing agent is preferable as the curing agent. From the viewpoint of suppressing the dielectric constant and the dielectric loss tangent of the cured product, an active ester compound is preferable as the curing agent. Other curing agents other than a phenol curing agent and an active ester compound may be used as the curing agent. Other curing agents may include an acid anhydride curing agent, an amine curing agent, etc.

The resin composition for molding may contain only one type of curing agent, or may contain two or more types.

In the case where the resin composition for molding includes two or more types of curing agents, two or more types of phenol curing agents may be used, two or more types of active ester compounds may be used, or a combination of a phenol curing agent and an active ester compound may be used.

### —Active Ester Compound—

Here, an active ester compound refers to a compound that possesses one or more ester groups in a single molecule that react with an epoxy group and has a curing effect on the epoxy resin.

By using an active ester compound as a curing agent, the dielectric constant and the dielectric loss tangent of the cured product can be suppressed to be lower than the case where a phenol curing agent is used alone as the curing agent. The reason for this is presumed to be as follows.

In the reaction between the epoxy resin and the phenol curing agent, a secondary hydroxyl group is generated. Comparatively, in the reaction between epoxy resin and the active ester compound, an ester group is generated instead of a secondary hydroxyl group. Since the ester group has a lower polarity than the secondary hydroxyl group, it is presumed that a resin composition for molding including an active ester compound as a curing agent can suppress the dielectric constant and the dielectric loss tangent of the cured product to be lower than a resin composition for molding including only a curing agent that generates a secondary hydroxyl group as a curing agent. Furthermore, polar groups in the cured product increase the water absorption of the cured product. By using an active ester compound as a curing agent, the polar group concentration in the cured product can be suppressed, and the water absorption of the cured product can be inhibited. By suppressing the water absorption of the cured product, in other words, by suppressing the content of H₂O that is a polar molecule, it is presumed that the dielectric constant and the dielectric loss tangent of the cured product can be further suppressed to be lower.

The active ester compound is not particularly limited in the type thereof as long as the active ester compound is a compound having one or more ester groups in the molecule that react with the epoxy group. Examples of the active ester compound include phenol ester compounds, thiophenol ester compounds, N-hydroxyamine ester compounds, and esterified heterocyclic hydroxy compounds.

Examples of the active ester compound include ester compounds obtained from at least one of aliphatic carboxylic acid and aromatic carboxylic acid, and at least one of an aliphatic hydroxy compound and an aromatic hydroxy compound. The ester compound that includes an aliphatic compound as a component of polycondensation tends to have excellent compatibility with an epoxy resin due to the presence of an aliphatic chain. The ester compound that includes an aromatic compound as a component of polycondensation tends to have excellent heat resistance due to the presence of an aromatic ring.

A specific example of the active ester compound includes an aromatic ester obtained by a condensation reaction between aromatic carboxylic acid and a phenolic hydroxyl group. Among the above, an aromatic ester obtained by a condensation reaction between an aromatic carboxylic acid and a phenolic hydroxyl group is preferred, by using as raw materials a mixture of: an aromatic carboxylic acid component in which 2 to 4 hydrogen atoms of an aromatic ring are substituted with carboxyl groups, such as benzene, naphthalene, biphenyl, diphenylpropane, diphenylmethane, diphenyl ether, diphenylsulfonic acid, etc.; a monovalent phenol in which one hydrogen atom of the aromatic ring is substituted with a hydroxyl group; and a polyvalent phenol in which 2 to 4 hydrogen atoms of the aromatic ring are substituted with hydroxyl groups. In other words, an aromatic ester having a structural unit derived from the aromatic carboxylic acid component, a structural unit derived from the monovalent phenol, and a structural unit derived from the polyvalent phenol is preferred.

As a specific example of the active ester compound, examples may include an active ester resin having a structure obtained by reacting a phenol resin having a molecular structure in which phenol compounds are linked via an aliphatic cyclic hydrocarbon group, an aromatic dicarboxylic acid or a halide thereof, and an aromatic monohydroxy compound, as described in Japanese Patent Application Laid-Open Publication No. 2012-246367. As the active ester resin, a compound represented by the following structural formula (1) is preferred.

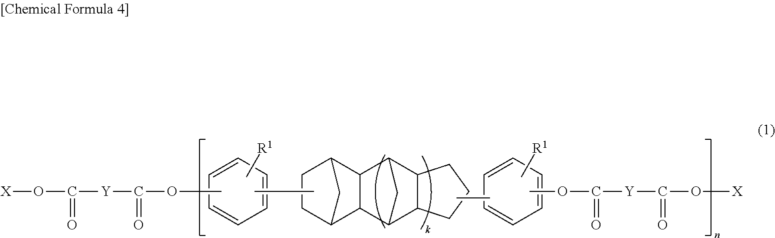

In Structural Formula (1), R¹ is a hydrogen atom, an alkyl group having 1 to 4 carbon atoms, or a phenyl group; X is an unsubstituted benzene ring, an unsubstituted naphthalene ring, a benzene ring or a naphthalene ring substituted with an alkyl group having 1 to 4 carbon atoms, or is a biphenyl group; Y is a benzene ring, a naphthalene ring, or a benzene ring or a naphthalene ring substituted with an alkyl group having 1 to 4 carbon atoms; k is 0 or 1; and n represents the average number of repetitions and is 0 to 5.

As specific examples of compounds represented by Structural Formula (1), exemplary compounds (1-1) to (1-10) shown below can be listed. In the Structural Formulas, t-Bu represents a tert-butyl group.

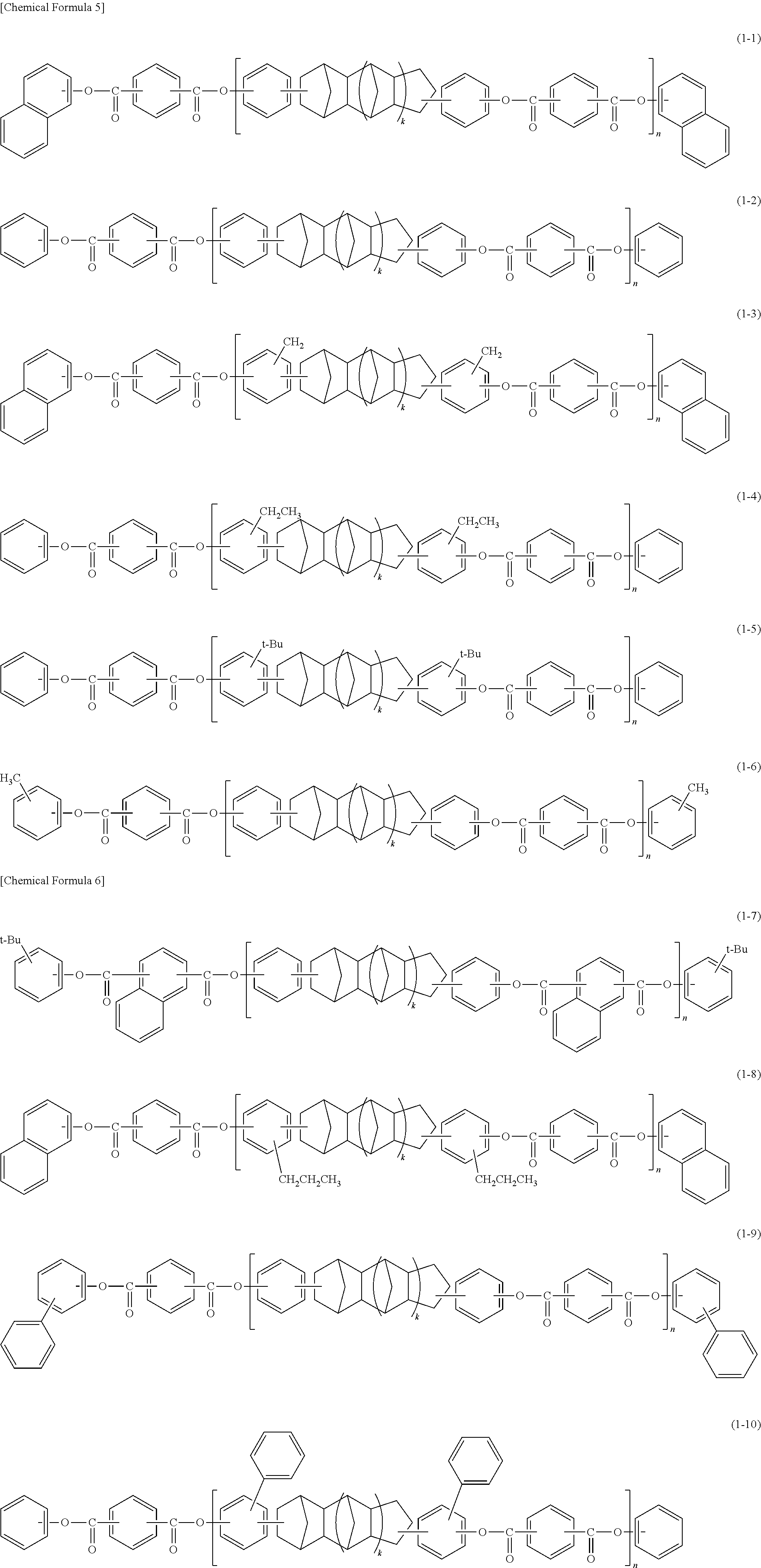

As another specific example of the active ester compound, examples may include compounds represented by the following Structural Formula (2) and compounds represented by the following Structural Formula (3), as described in Japanese Patent Application Laid-Open Publication No. 2014-114352.

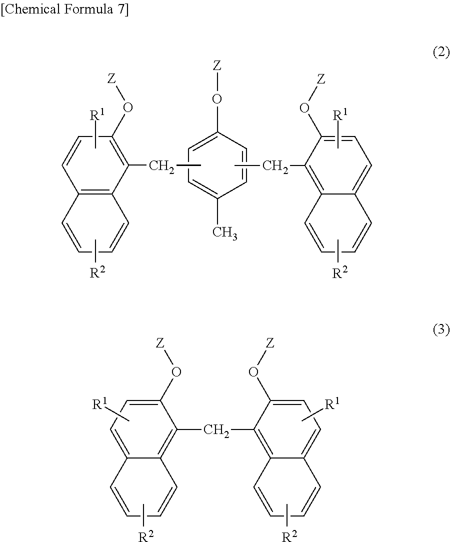

In Structural Formula (2), R¹ and R² are each independently a hydrogen atom, an alkyl group having 1 to 4 carbon atoms, or an alkoxy group having 1 to 4 carbon atoms; Z is an ester-forming structural part (z1) selected from the group consisting of an unsubstituted benzoyl group, an unsubstituted naphthoyl group, a benzoyl group or naphthoyl group substituted with an alkyl group having 1 to 4 carbon atoms, and an acyl group having 2 to 6 carbon atoms, or a hydrogen atom (z2); and at least one of Z is the ester-forming structural part (z1).

In Structural Formula (3), R¹ and R² are each independently a hydrogen atom, an alkyl group having 1 to 4 carbon atoms, or an alkoxy group having 1 to 4 carbon atoms; Z is an ester-forming structural part (z1) selected from the group consisting of an unsubstituted benzoyl group, an unsubstituted naphthoyl group, a benzoyl group or naphthoyl group substituted with an alkyl group having 1 to 4 carbon atoms, and an acyl group having 2 to 6 carbon atoms, or a hydrogen atom (z2); and at least one of Z is the ester-forming structural part (z1).

As specific examples of compounds represented by Structural Formula (2), exemplary compounds (2-1) to (2-6) shown below can be listed.

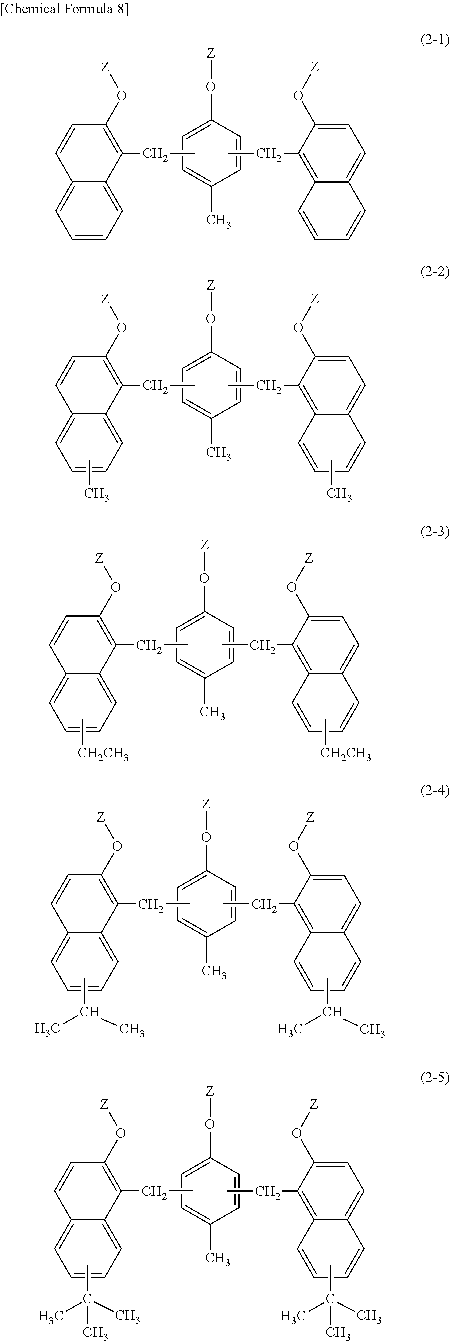

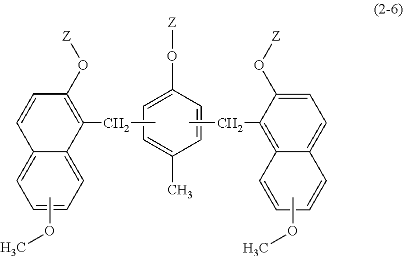

As specific examples of compounds represented by Structural Formula (3), exemplary compounds (3-1) to (3-6) shown below can be listed.

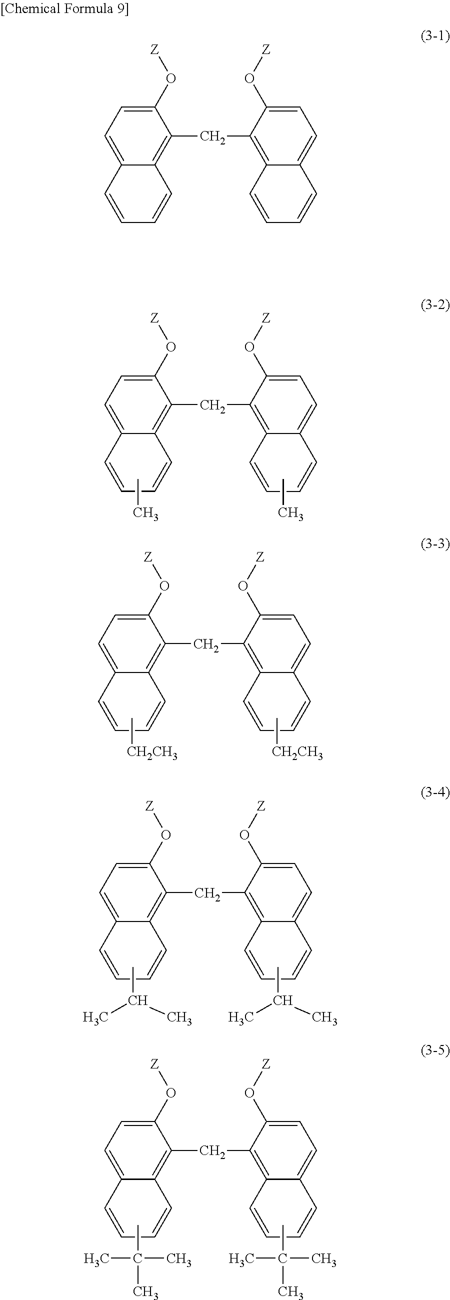

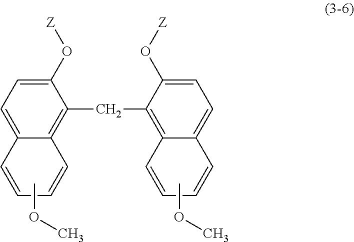

Commercially available products may be used as the active ester compound. Examples of the commercially available active ester compound include: “EXB9451”, “EXB9460”, “EXB9460S”, “HPC-8000-65T” (manufactured by DIC Corporation) as an active ester compound including a dicyclopentadiene-type diphenol structure; “EXB9416-70BK”, “EXB-8”, “EXB-9425” (manufactured by DIC Corporation) as an active ester compound including an aromatic structure; “DC808” (manufactured by Mitsubishi Chemical Corporation) as an active ester compound including an acetylated phenol novolac; “YLH1026” (manufactured by Mitsubishi Chemical Corporation) as an active ester compound including a benzoylated phenol novolac; and the like.

The ester equivalent (molecular weight/number of ester groups) of the active ester compound is not particularly limited. From the viewpoint of balancing various properties such as moldability, reflow resistance, and electrical reliability, 150 g/eq to 400 g/eq is preferable, 170 g/eq to 300 g/eq is more preferable, and 200 g/eq to 250 g/eq is even more preferable. The ester equivalent of the active ester compound is defined as a value measured according to the method conforming to JIS K 0070:1992.

### —Phenol Curing Agent—

Specific examples of the phenol curing agent include: a polyphenol compound such as resorcinol, catechol, bisphenol A, bisphenol F, substituted or unsubstituted biphenol; a novolac-type phenol resin obtained by condensation or co-condensation under an acidic catalyst of at least one phenolic compound selected from the group consisting of a phenol compound such as phenol, cresol, xylenol, resorcinol, catechol, bisphenol A, bisphenol F, phenylphenol, aminophenol, and a naphthol compound such as α-naphthol, β-naphthol, dihydroxynaphthalene, with an aldehyde compound such as formaldehyde, acetaldehyde, propionaldehyde; an aralkyl-type phenol resin such as phenol aralkyl resin and naphthol aralkyl resin synthesized from the phenolic compound and dimethoxy paraxylene, bis(methoxymethyl)biphenyl, etc.; a paraxylylene-modified phenol resin, a metaxylylene-modified phenol resin; a melamine-modified phenol resin; a terpene-modified phenol resin; a dicyclopentadiene-type phenol resin and a dicyclopentadiene-type naphthol resin synthesized by copolymerization of the phenolic compound with dicyclopentadiene; a cyclopentadiene-modified phenol resin; a polycyclic aromatic ring-modified phenol resin; a biphenyl-type phenol resin; a triphenylmethane-type phenol resin obtained by condensation or co-condensation under an acidic catalyst of the phenolic compound with an aromatic aldehyde compound such as benzaldehyde, salicylaldehyde; and phenol resin obtained by copolymerization of two or more of types. The phenol curing agents can be used alone or in combination of two or more.

The hydroxyl equivalent of the phenol curing agent is not particularly limited. From the viewpoint of balancing various properties such as moldability, reflow resistance, and electrical reliability, the hydroxyl equivalent of the phenol curing agent is preferably 70 g/eq to 1000 g/eq. and more preferably 80 g/eq to 500 g/eq.

The hydroxyl equivalent of the phenol curing agent is defined as a value measured according to the method conforming to JIS K 0070:1992.

The equivalent ratio of the epoxy resin to the curing agent, that is, the ratio of the number of functional groups in the curing agent to the number of functional groups in the epoxy resin (number of functional groups in the curing agent/number of functional groups in the epoxy resin), is not particularly limited. From the viewpoint of suppressing the respective unreacted portions, the ratio is preferably set in the range of 0.5 to 2.0, and more preferably set in the range of 0.6 to 1.3. From the viewpoint of moldability and reflow resistance, it is further preferably set in the range of 0.8 to 1.2.

In the case where an active ester compound and the phenol curing agent are used in combination as a curing agent, the molar ratio between the ester group contained in the active ester compound and the phenol hydroxyl group contained in the phenol curing agent (ester groups/phenol hydroxyl group) is preferably 9/1 to 1/9, more preferably 8/2 to 2/8, and further preferably 3/7 to 7/3.

In the case where an active ester compound and the phenol curing agent are used in combination as a curing agent, the mass ratio of the active ester compound in the total amount of the active ester compound and the phenol curing agent is preferably 40 mass % to 90 mass %, more preferably 50 mass % to 80 mass %, and further preferably 55 mass % to 70 mass %, from the viewpoint of excellent bending strength after the resin composition for molding is cured and from the viewpoint of suppressing the dielectric loss tangent of the cured product to a low level.

In the case where an active ester compound and the phenol curing agent are used in combination as a curing agent, the mass ratio of the phenol curing agent in the total amount of the active ester compound and the phenol curing agent is preferably 10 mass % to 60 mass %, more preferably 20 mass % to 50 mass %, and further preferably 30 mass % to 45 mass %, from the viewpoint of excellent bending strength after the resin composition for molding is cured and from the viewpoint of suppressing the dielectric loss tangent of the cured product to a low level.

The softening point or the melting point of the curing agent is not particularly limited. From the viewpoint of moldability and reflow resistance, the softening point or the melting point of the curing agent is preferably 40° C. to 180° C., and from the viewpoint of handling during the manufacture of the resin composition for molding, the softening point or the melting point is more preferably 50° C. to 130° C.

The melting point or the softening point of the curing agent is defined as a value measured in the same manner as the melting point or the softening point of the epoxy resin.

### (Inorganic Filler)

The resin composition for molding of the disclosure includes an inorganic filler. The type of the inorganic filler is not particularly limited. Specifically, examples of inorganic materials may include silica including fused silica and crystalline silica, glass, alumina, aluminum nitride, boron nitride, talc, clay, mica, calcium titanate, and barium titanate, etc. An inorganic filler having a flame-retardant effect may also be used. As the inorganic filler having a flame-retardant effect, examples may include: aluminum hydroxide, magnesium hydroxide, composite metal hydroxide such as composite hydroxide of magnesium and zinc, zinc borate, and the like.

Among the inorganic fillers, silica such as fused silica is preferred from the viewpoint of reducing the coefficient of linear expansion, and alumina is preferred from the viewpoint of high thermal conductivity. From the viewpoint of further reducing the dielectric loss tangent, boron nitride is preferred. The inorganic filler may be used alone or in combination of two or more types. The form of the inorganic filler includes powder, beads formed by spheroidizing powder, fibers, and the like.

The average particle size of the inorganic filler is not particularly limited. For example, the volume average particle size is preferably 0.2 μm to 50 μm, and more preferably 0.5 μm to 30 μm.

When the volume average particle size is 0.2 μm or more, there is a tendency in which the increase in viscosity of the resin composition for molding is further suppressed. When the volume average particle size is 50 μm or less, there is a tendency in which the filling ability into narrow gaps is improved. The volume average particle size of the inorganic filler refers to the value measured as the volume average particle size (D50) by a laser diffraction scattering particle size distribution measuring device.

The volume average particle size of the inorganic filler in the resin composition for molding or the cured product thereof can be measured by conventional techniques. As an example, the inorganic filler can be extracted from the resin composition for molding or the cured product by using an organic solvent, nitric acid, aqua regia, etc., and a dispersion liquid can be prepared by sufficiently dispersing the inorganic filler by using an ultrasonic disperser, etc. By using this dispersion liquid, the volume average particle size of the inorganic filler can be measured from the volume-based particle size distribution measured by the laser diffraction scattering particle size distribution measuring device. Alternatively, the volume average particle size of the inorganic filler can be measured from the volume-based particle size distribution obtained by embedding the cured product in a transparent epoxy resin or the like, polishing the product to obtain a cross-section, and observing the cross-section with a scanning electron microscope. Furthermore, it can also be measured by performing a three-dimensional structure analysis by continuously observing a two-dimensional cross-section of the cured product by using a focused ion beam SEM (FIB device) or the like.

From the viewpoint of flowability of the resin composition for molding, the particle shape of the inorganic filler is preferably spherical rather than angular, and the particle size distribution of the inorganic filler is preferably distributed over a wide range.

The content ratio of the total inorganic filler included in the resin composition for molding is, with respect to the entire resin composition for molding, preferably more than 50 volume %, more preferably more than 55 volume %, further preferably more than 55 volume % and 90 volume % or less, and particularly preferably 60 volume % to 85 mass %, from the viewpoint of controlling the flowability and the strength of the cured product of the resin composition for molding.

In the resin composition for molding, the content ratio (volume %) of the inorganic filler can be determined by the following method.

A thin slice sample of the cured product of the resin composition for molding is imaged by using a scanning electron microscope (SEM). In the SEM image, an arbitrary area S is identified, and a total area A of the inorganic filler contained in the area S is determined. The value obtained by dividing the total area A of the inorganic filler by the area S is converted to a percentage (%), and the value is considered as the content ratio (volume %) of the inorganic filler in the resin composition for molding.

The area S should be sufficiently larger than the size of the inorganic filler. For example, the area S should be large enough to contain 100 or more inorganic fillers. The area S may be the sum of multiple cross-sectional areas.

In the inorganic filler, a bias may be present in the presence ratio in the gravity direction during the curing of the resin composition for molding. In such a case, when imaging with SEM, the entirety of the cured product in the gravity direction is imaged, and the area S that includes the entirety of the cured product in the gravity direction is identified.

### (Release Agent)

The resin composition for molding of the disclosure includes a release agent from the viewpoint of obtaining favorable release properties from the mold during molding. The release agent is not particularly limited, and conventional release agents may be used. Specifically, examples may include carnauba wax, montan acid, a higher fatty acid such as stearic acid, a metal salt of a higher fatty acid, an ester-based wax such as montan acid ester, a polyolefin-based wax such as oxidized polyethylene and non-oxidized polyethylene. The release agent may be used alone or in combination of two or more types.

From the viewpoint of release properties, flowability, and package contamination, it is preferable that the release agent includes a polyolefin-based wax, and more preferably includes polyethylene oxide. The polyethylene oxide may be a linear polyethylene oxide or a branched polyethylene oxide. A combination of a linear polyethylene oxide and a branched polyethylene oxide may also be used.

Here, the linear polyethylene oxide refers to a polyethylene oxide where the number of carbon atoms in the side chain alkyl chain is about 10% or less of the number of carbon atoms in the main chain alkyl chain. Generally, a polyethylene oxide with a needle penetration of 2 or less is classified as a linear polyethylene oxide. Compared to a branched polyethylene oxide of the same molecular weight and acid value, a linear polyethylene oxide tends to have higher alkyl chain efficiency, is more likely to exude from the base resin, and has higher release properties. The tendency becomes more pronounced as the blending amount of the inorganic filler increases and as the weight average molecular weight of the linear polyethylene oxide increases.

From the viewpoint of release properties, it is preferable that the weight average molecular weight of the polyethylene oxide is 2800 or more. From the viewpoint of adhesion and prevention of mold and package contamination, it is preferable that the weight average molecular weight of the polyethylene oxide is 30000 or less. A range of 2800 to 30000 is more preferable, 2900 to 20000 is even more preferable, and 3000 to 15000 is particularly preferable. Here, the weight average molecular weight refers to a value measured by high-temperature GPC.

The measurement method is as follows.
Measuring instrument: High-temperature GPC manufactured by Waters Corporation
Column: Two columns of PLgel 10 μm MIXED-B (7.5 mm×300 mm) manufactured by Polymer Laboratories
Flow rate: 1.0 ml/min (sample concentration: 0.3 w/vol %)
Injection volume: 100 μl

From the viewpoint of balance between package contamination and mold release properties, it is preferable that the acid value of the polyethylene oxide is 2 mgKOH/g to 50 mgKOH/g, more preferably 10 mgKOH/g to 40 mgKOH/g, and even more preferably 15 mgKOH/g to 30 mgKOH/g. If the acid value is 5 mgKOH/g or more, there is a tendency in which package contamination is more easily suppressed. If the acid value is 50 mgKOH/g or less, there is a tendency for further improving mold release properties.

In the disclosure, the acid value of the polyethylene oxide is defined as the value measured according to the method conforming to JIS K 5902:1969.

The content of the release agent is preferably 1 part by mass to 30 parts by mass, more preferably 5 parts by mass to 25 parts by mass, and even more preferably 7 parts by mass to 20 parts by mass, with respect to 100 parts by mass of the sulfur atom-containing epoxy resin. When the amount of the release agent is 1 part by mass or more with respect to 100 parts by mass of the sulfur atom-containing epoxy resin, there is a tendency for obtaining sufficient release properties. When the amount of the release agent is 30 parts by mass or less, there is a tendency for more favorable adhesion.

The content of the release agent is preferably 0.01 parts by mass to 10 parts by mass, more preferably 0.1 parts by mass to 5 parts by mass, with respect to 100 parts by mass of the total of the epoxy resin and the curing agent. When the amount of the release agent is 0.01 parts by mass or more with respect to 100 parts by mass of the total of the epoxy resin and the curing agent, there is a tendency for obtaining sufficient release properties. When the amount of the release agent is 10 parts by mass or less, there is a tendency for more favorable adhesion.

In the case where the release agent includes polyethylene oxide, the content of the polyethylene oxide is preferably 1 part by mass to 30 parts by mass, more preferably 5 parts by mass to 25 parts by mass, and even more preferably 7 parts by mass to 20 parts by mass, with respect to 100 parts by mass of the sulfur atom-containing epoxy resin. When the amount of the polyethylene oxide is 1 part by mass or more with respect to 100 parts by mass of the sulfur atom-containing epoxy resin, there is a tendency for obtaining sufficient release properties. When the amount of the polyethylene oxide is 30 parts by mass or less, there is a tendency for more favorable adhesion.

The content of the polyethylene oxide is preferably 0.01 parts by mass to 10 parts by mass, more preferably 0.1 parts by mass to 5 parts by mass, with respect to 100 parts by mass of the total of the epoxy resin and the curing agent. When the amount of the polyethylene oxide is 0.01 parts by mass or more with respect to 100 parts by mass of the total of the epoxy resin and the curing agent, there is a tendency for obtaining sufficient release properties. When the amount of the polyethylene oxide is 10 parts by mass or less, there is a tendency for more favorable adhesion.

### (Specific Copolymer)

The resin composition for molding of the disclosure includes a specific copolymer.

There is no particular limitation on the α-olefin with 5 to 30 carbon atoms used in the specific copolymer. Specific examples of α-olefin having 5 to 30 carbon atoms may include a linear α-olefin such as 1-pentene, 1-hexene, 1-heptene, 1-octene, 1-nonene, 1-decene, 1-undecene, 1-dodecene, 1-tridecene, 1-tetradecene, 1-pentadecene, 1-hexadecene, 1-heptadecene, 1-octadecene, 1-nonadecene, 1-eicosene, 1-docosene, 1-tricosene, 1-tetracosene, 1-pentacosene, 1-hexacosene, 1-heptacosene, and a branched α-olefin such as 3-methyl-1-butene, 3,4-dimethyl-pentene, 3-methyl-1-nonene, 3,4-dimethyl-octene, 3-ethyl-1-dodecene, 4-methyl-5-ethyl-1-octadecene, 3,4,5-triethyl-1-1-eicosene. The α-olefins can be used alone or in combination of two or more types. Among the α-olefins, a linear α-olefin with 10 to 25 carbon atoms is preferable, and a linear α-olefin with 15 to 25 carbon atoms such as 1-eicosene, 1-docosene, 1-tricosene is more preferable.

As a maleic anhydride derivative used in the specific copolymer, methylmaleic anhydride, dimethylmaleic anhydride, etc., can be mentioned.

The specific copolymer preferably includes a structural unit represented by General Formula (C) as follows and a structural unit represented by General Formula (D) as follows.

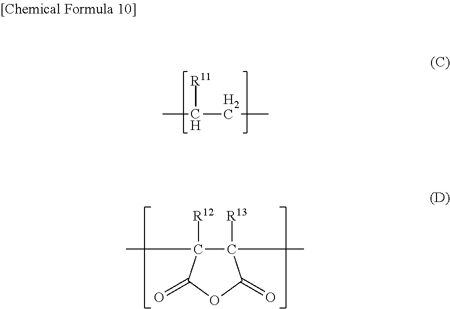

In General Formula (C) and General Formula (D), R¹¹ represents a monovalent aliphatic hydrocarbon group having 3 to 28 carbon atoms, and R¹² and R¹³ each independently represent a hydrogen atom, an alkyl group, or an aryl group.

Specific examples of the monovalent aliphatic hydrocarbon group having 3 to 28 carbon atoms represented by R¹¹ in General Formula (C) include a monovalent residue obtained by removing the portion of an ethenyl group (—CH═CH₂) from the α-olefin having 5 to 30 carbon atoms. As R¹¹, a linear hydrocarbon group with 13 to 23 carbon atoms is preferable, and a linear hydrocarbon group with 18 to 21 carbon atoms such as an n-octadecyl group, an n-eicosyl group, an n-heneicosyl group is more preferable.

In General Formula (D), the alkyl group represented by R¹² or R¹³ includes an alkyl group with 1 to 4 carbon atoms, and a methyl group is preferable.

In General Formula (D), the aryl group represented by R¹² or R¹³ is preferably a phenyl group. In General Formula (D), R¹² or R¹³ is preferably a hydrogen atom.

The copolymerization ratio between the structural unit represented by General Formula (C) and the structural unit represented by General Formula (D) is not particularly limited. However, in the case where the structural unit represented by General Formula (C) is X moles and the structural unit represented by General Formula (D) is Y moles, X/Y is preferably 1/2 to 10/1, more preferably 2/3 to 5/1, even more preferably 3/4 to 2/1, and particularly preferably around 1/1, which is substantially equimolar.

In the case where the structural unit represented by General Formula (C) and the structural unit represented by General Formula (D) are bonded, the structural units may be in either state of General Formulae (E) and (F) as follows. In the following General Formula (E) and General Formula (F), specific examples and preferred examples of R¹¹ to R¹³ are the same as in the case of General Formula (C) and General Formula (D).

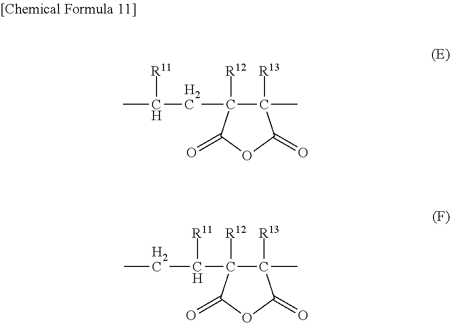

The specific copolymer may have any structure such as a random, a block, or a graft copolymer.

In the case where the specific copolymer includes the structural unit represented by General Formula (C) and the structural unit represented by General Formula (D), the specific copolymer may or may not include an other structural unit other than the structural units represented by General Formula (C) and General Formula (D). The ratio of such other structural unit in all structural units of the specific copolymer is preferably 0 mol % to 50 mol %, more preferably 0 mol % to 35 mol %, and even more preferably 0 mol % to 20 mol %.

In the specific copolymer, at least a portion of the structural units derived from at least one of the maleic anhydride and the maleic anhydride derivative included in the specific copolymer may be hydrolyzed, and a carboxyl group may be provided.

The manufacturing method of the specific copolymer is not particularly limited, and general copolymerization techniques such as reacting raw materials can be used. For the reaction, an organic solvent in which α-olefin and maleic anhydride are soluble may be used. The organic solvent is not particularly limited, but toluene is preferred, and an alcohol-based solvent, an ether-based solvent, an amine-based solvent, etc., can also be used. The reaction temperature varies depending on the type of the organic solvent used. Nevertheless, from the viewpoint of reactivity, productivity, etc., the reaction temperature is preferably 50° C. to 200° C., and more preferably 80° C. to 120° C. The reaction time is not particularly limited as long as the specific copolymer is obtained, but from the viewpoint of productivity, the reaction time is preferably 1 hour to 30 hours, more preferably 2 hours to 15 hours, and even more preferably 4 hours to 10 hours. After the reaction is completed, unreacted components, organic solvents, etc. can be removed under a heated reduced pressure, if necessary. The condition is preferably a temperature of 100° C. to 220° C., more preferably 120° C. to 180° C., a pressure of 13.3×10³ Pa or less, more preferably 8×10³ Pa or less, and a time of 0.5 hours to 10 hours. In addition, a reaction catalyst such as an amine-based catalyst, an acid catalyst, etc., may be added to the reaction as needed. The pH of the reaction system is preferably around 1 to 10.

The specific copolymer may also be a commercially available product. As a commercially available product, Nissan Electol WPB-1 (product name of NOF Corporation), which uses 1-eicosene, 1-docosene, and 1-tricosene as raw materials, is available.

The weight average molecular weight of the specific copolymer is preferably 5000 to 100000, more preferably 10000 to 70000, and even more preferably 15000 to 50000 from the viewpoint of preventing mold and package contamination and moldability. If the weight average molecular weight is 5000 or more, a sufficient effect in preventing mold and package contamination tends to be rendered, and if the weight average molecular weight is 100000 or less, the deterioration in kneadability, etc., tend to be suppressed without excessively raising the softening point of the specific copolymer.

The weight average molecular weight of the specific copolymer is measured by gel permeation chromatography (GPC) and derived through conversion using a standard polystyrene calibration curve. The GPC conditions are as follows.

### —GPC Conditions—

Pump: Hitachi L-6000 type (manufactured by Hitachi, Ltd.)
Columns: The following 3 columns
Gelpack GL-R420
Gelpack GL-R430
Gelpack GL-R440
(the above are names of products manufactured by Showa Denko Materials Techno Service Co., Ltd.)
Eluent: Tetrahydrofuran
Measurement temperature: 25° C.
Flow rate: 2.05 mL/min
Detector: Hitachi L-3300 type RI (manufactured by Hitachi, Ltd.)

The content of the specific copolymer is preferably 0.01 parts by mass to 10 parts by mass, more preferably 0.5 parts by mass to 5 parts by mass, and even more preferably 1 parts by mass to 4 parts by mass, with respect to 100 parts by mass of the sulfur atom-containing epoxy resin. When the amount of the specific copolymer is 10 part by mass or less with respect to 100 parts by mass of the sulfur atom-containing epoxy resin, there is a tendency for obtaining sufficient release properties. When the amount of the specific copolymer is 0.5 parts by mass or more, there is a tendency for the effect of improving the adhesion as well as mold/package contamination to be sufficient.

The content of the specific copolymer is preferably 0.01 parts by mass to 10 parts by mass, more preferably 0.1 parts by mass to 5 parts by mass, with respect to 100 parts by mass of the total of the epoxy resin and the curing agent. When the amount of the specific copolymer is 0.01 parts by mass or more with respect to 100 parts by mass of the total of the epoxy resin and the curing agent, there is a tendency for obtaining sufficient release properties. When the amount is 10 parts by mass or less, there is a tendency for the improvement effects on the adhesion and the mold/package contamination to be sufficient.

### (Curing Accelerator)

The resin composition for molding of the disclosure may include a curing accelerator when needed. The type of the curing accelerator is not particularly limited and can be selected according to the type of the epoxy resin, the desired properties of the resin composition for molding, etc.

As the curing accelerator, examples may include: diazabicycloalkene such as 1,5-diazabicyclo[4.3.0]non-5-ene (DBN), 1,8-diazabicyclo[5.4.0]undec-7-ene (DBU); a cyclic amidine compound such as 2-methylimidazole, 2-phenylimidazole, 2-phenyl-4-methylimidazole, 2-ethyl-4-methylimidazole, 2-heptadecylimidazole; a derivative of the cyclic amidine compound; a phenol novolac salt of the cyclic amidine compound or the derivative thereof; a compound having intramolecular polarization formed by adding to the compound a compound with a x-bond such as maleic anhydride, 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, phenyl-1,4-benzoquinone, and diazophenylmethane; a cyclic amidinium compound such as tetraphenylborate salt of DBU, tetraphenylborate salt of DBN, tetraphenylborate salt of 2-ethyl-4-methylimidazole, and tetraphenylborate salt of N-methylmorpholine, etc.; a tertiary amine compound such as pyridine, triethylamine, triethylenediamine, benzyldimethylamine, triethanolamine, dimethylaminoethanol, tris(dimethylaminomethyl)phenol; a derivative of the tertiary amine compound; an ammonium salt compound such as tetra-n-butylammonium acetate, tetra-n-butylammonium phosphate, tetraethylammonium acetate, tetra-n-hexylammonium benzoate, tetrapropylammonium hydroxide; an organic phosphine such as primary phosphines like ethylphosphine and phenylphosphine, secondary phosphines like dimethylphosphine and diphenylphosphine, tertiary phosphines like triphenylphosphine, diphenyl(p-tolyl)phosphine, tris(alkylphenyl)phosphine, tris(alkoxyphenyl)phosphine, tris(alkyl alkoxyphenyl)phosphine, tris(dialkylphenyl)phosphine, tris(trialkylphenyl)phosphine, tris(tetraalkylphenyl)phosphine, tris(dialkoxyphenyl)phosphine, tris(trialkoxyphenyl)phosphine, tris(tetraalkoxyphenyl)phosphine, trialkylphosphine, dialkylalylphosphine, alkyldiarylphosphine, trinaphthylphosphine, tris(benzyl)phosphine; a phosphine compound such as a complex of the organic phosphine with an organic boron; a compound having intramolecular polarization formed by adding to the organic phosphine or phosphine compound a compound with a x-bond such as maleic anhydride, 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, phenyl-1,4-benzoquinone, anthraquinone, and diazophenylmethane; a compound having intramolecular polarization obtained through a dehydrohalogenation process after reacting the organic phosphine or phosphine compound with a halogenated phenol compound such as 4-bromophenol, 3-bromophenol, 2-bromophenol, 4-chlorophenol, 3-chlorophenol, 2-chlorophenol, 4-iodophenol, 3-iodophenol, 2-iodophenol, 4-bromo-2-methylphenol, 4-bromo-3-methylphenol, 4-bromo-2,6-dimethylphenol, 4-bromo-3,5-dimethylphenol, 4-bromo-2,6-di-tert-butylphenol, 4-chloro-1-naphthol, 1-bromo-2-naphthol, 6-bromo-2-naphthol, 4-bromo-4′-hydroxybiphenyl; a tetra-substituted phosphonium compound, such as tetra-substituted phosphonium such as a tetraphenylphosphonium; tetraphenylborate salt of tetra-substituted phosphonium such as tetraphenylphosphonium tetra-p-tolylborate: tetraphenylborate salts of tetra-substituted phosphonium, a salt of tetra-substituted phosphonium with a phenolic compound, a salt of tetraalkylphosphonium with a portion of a hydrolysis product of aromatic carboxylic acid anhydride; a phosphobetaine compound; an adduct of a phosphonium compound with a silane compound.

The curing accelerator may be used alone or in combination of two or more types.

Among the above, it is preferable that the curing accelerator is a curing accelerator including organic phosphine. As the curing accelerator including organic phosphine, examples may include the organic phosphine, a phosphine compound such as a complex of the organic phosphine with an organic boron compound, a compound having intramolecular polarization formed by adding a compound having a x-bond to the organic phosphine or the phosphine compound, etc.

Among the above, as a particularly preferable curing accelerator, examples may include triphenylphosphine, an adduct of triphenylphosphine with a quinone compound, an adduct of tributylphosphine with a quinone compound, an adduct of tri-p-tolylphosphine with a quinone compound, and the like.

In the case where the resin composition for molding includes a curing accelerator, the amount of the curing accelerator is preferably 0.1 parts by mass to 30 parts by mass, and more preferably 1 part by mass to 15 parts by mass, with respect to 100 parts by mass of the total of the epoxy resin and the curing agent. When the amount of the curing accelerator is 0.1 parts by mass or more with respect to 100 parts by mass of the total of the epoxy resin and the curing agent, there is a tendency of curing favorably within a short time. When the amount of the curing accelerator is 30 parts by mass or less with respect to 100 parts by mass of the total of the epoxy resin and the curing agent, there is a tendency for a good molded product to be obtained without an excessively fast curing speed.

### (Stress Relief Agent)

The resin composition for molding of the disclosure may include a stress relief agent. By including a stress relief agent, the warpage deformation of the package and the occurrence of package cracks can be further reduced. As the stress relief agent, conventionally stress relief agents (flexibilizers) that are generally used can be listed. Specifically, examples may include a thermoplastic elastomer such as a silicone-based, styrene-based, olefin-based, urethane-based, polyester-based, polyether-based, polyamide-based, polybutadiene-based elastomer; an indene-styrene-cumarone copolymer, triphenylphosphine oxide, phosphate esters and other organic phosphorus compounds; rubber particles such as natural rubber (NR), acrylonitrile-butadiene rubber (NBR), acrylic rubber, urethane rubber, silicone powder; rubber particles having a core-shell structure such as methyl methacrylate-styrene-butadiene copolymer (MBS), methyl methacrylate-silicone copolymer, methyl methacrylate-butyl acrylate copolymer. The stress relief agent may be used alone or in combination of two or more types.

As the silicone-based stress relief agent, those having an epoxy group, those having amino groups, and those modified with polyether, and a silicone compound such as a silicone compound having an epoxy group and a polyether-based silicone compound are more preferred.

From the viewpoint of dielectric loss tangent, it is preferable that the stress relief agent includes at least one of an indene-styrene-coumarone copolymer and a triphenylphosphine oxide.

In the case where the resin composition for molding includes a stress relief agent, the amount of the stress relief agent is, for example, preferably 1 part by mass to 35 parts by mass, and more preferably 2 parts by mass to 34 parts by mass, with respect to 100 parts by mass of the total of the epoxy resin and the curing agent.

In the case where the stress relief agent includes at least one of an indene-styrene-coumarone copolymer and a triphenylphosphine oxide, the amount thereof is, for example, preferably 1 part by mass to 30 parts by mass, and more preferably 2 parts by mass to 20 parts by mass, with respect to 100 parts by mass of the total of the epoxy resin and the curing agent.

The content of the silicone-based stress relief agent may be, for example, 2 parts by mass or less, or 1 part by mass or less, with respect to 100 parts by mass of the total of the epoxy resin and the curing agent. The resin composition for molding may not include a silicone-based stress relief agent. The lower limit of the content of the silicone-based stress relief agent is not particularly limited, and may be 0 parts by mass or 0.1 parts by mass.

From the viewpoint of dielectric loss tangent, the content ratio of the silicone-based stress relief agent is preferably 20 mass % or less, more preferably 10 mass % or less, further preferably 7 mass % or less, particularly preferably 5 mass % or less, and extremely preferably 0.5 mass % or less, with respect to the entire resin composition for molding. The lower limit of the content ratio of the silicone-based stress relief agent is not particularly limited, and may be 0 mass % or 0.1 mass %.

### [Various Additives]

The resin composition for molding of the disclosure may include, in addition to the above components, various additives exemplified below, such as a coupling agent, an ion exchanger, a flame retardant, a colorant, and the like. The resin composition for molding of the disclosure may, as needed, include additives familiar for those in the technical field, in addition to the additives exemplified below.

### (Coupling Agent)

The resin composition for molding of the disclosure may include a coupling agent. From the viewpoint of improving the adhesion between the epoxy resin and the curing agent and the inorganic filler, it is preferable that the resin composition for molding includes a coupling agent. As the coupling agent, examples may include conventional coupling agents, such as a silane-based compound such as epoxysilane, mercaptosilane, aminosilane, alkylsilane, ureidosilane, vinylsilane, disilazane, a titanium-based compound, an aluminum chelate-based compound, an aluminum/zirconium-based compound.

In the case where the resin composition for molding includes a coupling agent, the amount of the coupling agent is preferably 0.05 parts by mass to 5 parts by mass, and more preferably 0.1 parts by mass to 2.5 parts by mass, with respect to 100 parts by mass of the inorganic filler. When the amount of the coupling agent is 0.05 parts by mass or more with respect to 100 parts by mass of the inorganic filler, there is a tendency for the adhesion to improve further. When the amount of the coupling agent is 5 parts by mass or less with respect to 100 parts by mass of the inorganic filler, there is a tendency for the moldability of the package to improve further.

### (Ion Exchanger)

The resin composition for molding of the disclosure may include an ion exchanger. From the viewpoint of improving moisture resistance and high-temperature storage properties of an electronic component device including a sealed electronic component, it is preferable that the resin composition for molding includes an ion exchanger. The ion exchanger is not particularly limited, and conventional ion exchangers can be used. Specifically, examples may include a hydrotalcite compound, and a hydrated hydroxide of at least one element selected from the group consisting of magnesium, aluminum, titanium, zirconium, and bismuth. The ion exchanger may be used alone or in combination of two or more types. Among the above, hydrotalcite represented by the following general formula (A) is preferred.

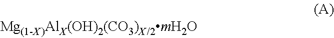

(0<X≤0.5, m being a positive number)

In the case where the resin composition for molding includes an ion exchanger, the content of the ion exchanger is not particularly limited as long as it is sufficient to capture ions such as halogen ions. For example, the content of the ion exchanger is preferably 0.1 parts by mass to 30 parts by mass, more preferably 1 part by mass to 10 parts by mass, with respect to 100 parts by mass of the total of the epoxy resin and the curing agent.

### (Flame Retardant)

The resin composition for molding of the disclosure may include a flame retardant. The flame retardant is not particularly limited, and conventionally flame retardants can be used.

Specifically, examples may include an organic or inorganic compound containing halogen atoms, antimony atoms, nitrogen atoms or phosphorus atoms, and metal hydroxides. The flame retardant may be used alone or in combination of two or more types.

In the case where the resin composition for molding includes a flame retardant, the amount of the flame retardant is not particularly limited as long as it is sufficient to obtain the desired flame retardant effect. For example, the amount of the flame retardant is preferably 1 part by mass to 30 parts by mass, more preferably 2 parts by mass to 20 parts by mass, with respect to 100 parts by mass of the total of the epoxy resin and the curing agent.

### (Colorant)

The resin composition for molding of the disclosure may include a colorant. As the colorant, examples may include conventional colorants such as carbon black, organic dyes, organic pigments, titanium oxide, red lead, and bengala. The content of the colorant can be appropriately selected according to the purpose, etc. The colorant may be used alone or in combination of two or more types.

### (Preparation Method of the Resin Composition for Molding)

The preparation method of the resin composition for molding is not particularly limited. As a general technique, examples may include a method in which components in predetermined blending amounts are sufficiently mixed by a mixer or the like, then melt-kneaded by a mixing roll, an extruder, etc., cooled, and pulverized. More specifically, examples may include a method in which the components in predetermined amounts are stirred and mixed, kneaded in a kneader, a roll, an extruder, or the like, preheated to 70° C. to 140° C., cooled, and pulverized.

The resin composition for molding of the disclosure is preferably solid under normal temperature and pressure conditions (for example, at 25° C. and atmospheric pressure). In the case where the resin composition for molding is a solid, the shape of the resin composition is not particularly limited, and examples may include a powder form, a granular form, a tablet form, etc. In the case where the resin composition for molding is in a tablet form, it is preferable from the viewpoint of handling that the dimension and the mass match the molding conditions of the package.

### (Properties of the Resin Composition for Molding)

The relative dielectric constant at 5 GHz of the cured product of the resin composition for molding of the disclosure may be, for example, 3.3 to 4.0. The relative dielectric constant at 5 GHz of the cured product is preferably 3.3 to 3.8, more preferably 3.3 to 3.6, and even more preferably 3.3 to 3.5 from the viewpoint of miniaturizing electronic components such as antennas.

The measurement of the relative dielectric constant is conducted by using a dielectric constant measurement device (for example, a cavity resonator) at a temperature of 25±3° C.

To set the relative dielectric constant at 5 GHz of the cured product in the range of 3.3 to 3.5, it is preferable to use an active ester compound as the curing agent.

The dielectric loss tangent at 5 GHz of the cured product of the resin composition for molding of the disclosure may be, for example, 0.08. The dielectric loss tangent at 10 GHz of the cured product is preferably 0.04 or less, more preferably 0.02 or less, and even more preferably 0.01 or less from the viewpoint of reducing transmission loss. The lower limit of the dielectric loss tangent at 5 GHz of the cured product is not particularly limited. For example, the lower limit of the dielectric loss tangent may be 0.001, for example.

The measurement of the dielectric loss tangent is conducted by using a dielectric constant measurement device (for example, a cavity resonator) at a temperature of 25+3° C.

To set the dielectric loss tangent at 5 GHz of the cured product to be less than 0.01, it is preferable to use an active ester compound as the curing agent.

### (Uses of the Resin Composition for Molding)

The resin composition for molding of the disclosure can be applied, for example, to the manufacture of electronic component devices, particularly high-frequency devices, as described later. The resin composition for molding of the disclosure may also be used for sealing electronic components in high-frequency devices. In the case of sealing electronic components in high-frequency devices by using the resin composition for molding, it is preferable to use an active ester compound as the curing agent.

In particular, in recent years, with the widespread adoption of the fifth-generation mobile communication system (5G), semiconductor packages (PKG) used in electronic component devices are becoming more advanced in functionality and smaller in size. Furthermore, along with the miniaturization and increased functionality of PKGs, the development of antenna-in-package (AiP), which is a PKG with antenna functionality, is also progressing. In AiPs, to cope with the increase in the number of channels due to the diversification of information, the radio waves used for communication are becoming higher in frequency, and sealing materials are required to achieve a low dielectric loss tangent and a low relative dielectric constant.

The resin composition for molding of the disclosure, as mentioned above, yields a cured product with a low dielectric loss tangent and a low relative dielectric constant by using an active ester compound as the curing agent. Therefore, it is particularly suitable for antenna-in-package (AiP) applications in high-frequency devices, where an antenna placed on a support member is sealed with the resin composition for molding.

In electronic component devices containing antennas, such as antenna-in-package, heat generation occurs due to power supply in the case where the amplifier for power supply is provided on the opposite side of the antenna. From the viewpoint of improving heat dissipation, the resin composition for molding used in the manufacture of electronic component devices preferably includes alumina particles as the inorganic filler.

### <Electronic Component Device>

The electronic component device according to the disclosure includes a support member, an electronic component disposed on the support member, and a cured product of the resin composition sealing the electronic component.

Examples of the electronic component device may include a device (e.g., a high-frequency device) in which an electronic component region obtained by mounting an electronic components (an active element such as a semiconductor chip, a transistor, a diode, and a thyristor; a passive element such as a capacitor, a resistor, and a coil; an antenna, etc.) on the support member such as a lead frame, a wired tape carrier, a wiring board, a glass, a silicon wafer, an organic substrate, etc., is sealed with the resin composition for molding.

The type of the support member is not particularly limited, and support members generally used in the manufacture of electronic component devices can be used.

The electronic component may include an antenna, or may include both an antenna and elements other than the antenna. The antenna is not limited as long as it serves the role of an antenna, and may be an antenna element or may be a wiring.

In addition, in the electronic component device of the disclosure, if necessary, other electronic components may be disposed on the surface on a side opposite to the surface on which the electronic component is disposed on the support member. Other electronic components may be sealed with the resin composition for molding, sealed with another resin composition, or not sealed.

### (Manufacturing Method of the Electronic Component Device)

The manufacturing method of the electronic component device according to the disclosure includes a step of placing an electronic component on a support member, and a step of sealing the electronic component with the resin composition for molding.

The method for implementing each step is not particularly limited, and can be carried out by general techniques.

In addition, the types of the support member and the electronic component used in the manufacture of the electronic component device are not particularly limited, and support members and electronic components generally used in the manufacture of electronic component devices can be used.

The method for sealing the electronic component by using the resin composition for molding includes low-pressure transfer molding, injection molding, and compression molding, etc. Among these, low-pressure transfer molding is common.

### EXAMPLES

In the following, the embodiment will be specifically described below with examples, but the scope of the embodiment is not limited to these examples.

### (Preparation of the Resin Composition for Molding)

The components shown below were mixed in the blending ratios (parts by mass) shown in Tables 1 and 2 to prepare resin compositions for molding of Examples and Comparative Examples. The resin compositions for molding were solid under normal temperature and pressure conditions.

In addition, the content ratio of the inorganic filler with respect to the entire resin composition for molding (referred to as “Filler amount (volume %)” in the tables) is also shown in Tables 1 to 2.
Epoxy resin 1: Triphenylmethane type epoxy resin (epoxy equivalent: 167 g/eq)
Epoxy resin 2: A compound represented by General Formula (B), in which, when the positions where oxygen atoms are substituted among R¹⁰ are designated as 4 and 4′ positions, the 3 and 3′ positions are tert-butyl groups, the 6 and 6′ positions are methyl groups, and the remaining R¹⁰ are hydrogen atoms (epoxy equivalent: 245 g/eq)
Epoxy resin 3: Bisphenol F type epoxy resin (epoxy equivalent: 193 g/eq)
Epoxy resin 4: Biphenyl aralkyl type epoxy resin (epoxy equivalent: 277 g/eq)
Epoxy resin 5: Biphenyl type epoxy resin (epoxy equivalent: 196 g/eq)
Epoxy resin 6: o-cresol novolac type epoxy resin (epoxy equivalent: 200 g/eq)
Curing agent 1: Triphenylmethane type phenol resin (hydroxyl equivalent: 106 g/eq)
Curing agent 2: Melamine-modified phenol resin (hydroxyl equivalent: 120 g/eq)
Curing agent 3: Biphenyl aralkyl type phenol resin (hydroxyl equivalent: 200 g/eq)
Curing agent 4: Active ester compound, DIC Corporation, product name “EXB-8”
Curing accelerator: Adduct of tributylphosphine and 1,4-benzoquinone
Coupling agent 1: Diphenyldimethoxysilane
Coupling agent 2: N-phenyl-3-aminopropyltrimethoxysilane
Coupling agent 3: Methyltrimethoxysilane
Coupling agent 4: 3-glycidoxypropyltrimethoxysilane
Release agent 1: Hoechst wax (Clariant Chemicals Co., Ltd., product name “HW-E”)
Release agent 2: Linear polyethylene oxide, weight average molecular weight 8800, acid value 30 mgKOH/g
Release agent 3: Branched polyethylene oxide, weight average molecular weight 3100, acid value 25 mgKOH/g
Release agent 4: Linear polyethylene oxide, weight average molecular weight 11000, acid value 30 mgKOH/g
Release agent 5: Polyethylene oxide, weight average molecular weight 7500, acid value 28 mgKOH/g
Specific copolymer: Copolymer, using 1-eicosene, 1-docosene, and 1-tricosene as raw materials, including a structural unit represented by General Formula (C) and a structural unit represented by General Formula (D), where the molar ratio X/Y between the structural unit represented by General Formula (C) and the structural unit represented by General Formula (D) is 1/1, R¹¹ in General Formula (C) is an n-octadecyl group, n-eicosyl group, or n-heneicosyl group, and R¹² and R¹³ in General Formula (D) are hydrogen atoms (weight average molecular weight: 20400)
Colorant agent: Carbon black
Additive 1: Silicone oil with an epoxy equivalent of 2900 g/eq and a viscosity of 2850 mm²/s (25° C.)
Additive 2: Triphenylphosphine oxide
Additive 3: Polysiloxane with an epoxy equivalent of 1660 g/eq and a softening point of 80° C.
Inorganic filler 1: Silica particles (volume average particle size: 0.6 μm)
Inorganic filler 2: Magnesium hydroxide particles (volume average particle size: 1.5 μm)
Inorganic filler 3: Silica particles (volume average particle size: 27 μm)
Inorganic filler 4: Silica particles (volume average particle size: 16 μm)
Inorganic filler 5: Silica particles (volume average particle size: 11 μm)
Inorganic filler 6: Silica particles (volume average particle size: 2.3 μm)
Inorganic filler 7: Silica particles (volume average particle size: 30 μm)
Inorganic filler 8: Silica particles (nanosilica particles with a specific surface area of 190 m²/g to 230 m²/g)
Inorganic filler 9: Silica particles (volume average particle size: 17 μm)
Inorganic filler 10: Silica particles (volume average particle size: 1.5 μm)
Inorganic filler 11: Silica particles (volume average particle size: 16 μm)
Inorganic filler 12: Silica particles (volume average particle size: 31 μm)
Inorganic filler 13: Silica particles (volume average particle size: 4.0 μm)
Inorganic filler 14: Silica particles (volume average particle size: 0.5 μm)

The volume average particle size of each of the inorganic fillers is obtained by the following measurement.

Specifically, first, the inorganic filler was added to a dispersion medium (water) in the range of 0.01 mass % to 0.1 mass %, and dispersed for 5 minutes by using a bath-type ultrasonic cleaner. 5 ml of the obtained dispersion liquid was injected into a cell, and the particle size distribution was measured at 25° C. by using the laser diffraction/scattering particle size distribution analyzer (LA920, HORIBA, Ltd.).

The particle size at the cumulative value of 50% (volume basis) in the obtained particle size distribution was defined as the volume average particle size.

The specific surface area of the inorganic filler 8 was determined as the value measured from nitrogen adsorption capacity in accordance with JIS Z 8830:2013.

### (Evaluation of Spiral Flow (SF))

By using a mold for measuring a spiral flow in accordance with EMMI-1-66, the resin composition for molding was molded by a transfer molding machine under the conditions of a mold temperature of 180° C., a molding pressure of 6.9 MPa, and a curing time of 120 seconds to determine the flow distance (inch). The results are shown in Tables 3 and 4.

### (Measurement of Gel Time (GT))

As a sample, 0.5 g of the resin composition for molding was placed on a hot plate heated to 175° C., and, by using a jig, the sample was uniformly spread into a circular shape with a diameter of 2.0 cm to 2.5 cm at a rotation speed of 20 to 25 rotations per minute.

The time from placing the sample on the hot plate until the sample lost its viscosity, became gel-like, and started to peel off from the hot plate was measured, and such time was defined as the gel time (sec). The results are shown in Tables 3 and 4.

### (Evaluation of High-Temperature Hardness)

The evaluation of high-temperature hardness of the thermosetting resin composition was conducted as follows.

The thermosetting resin composition was molded into a test piece (circular plate with a diameter of 50 mm×thickness of 3 mm) for measuring high-temperature hardness by using a transfer molding machine under the conditions of a mold temperature of 175° C. to 180° C., a molding pressure of 6.9 MPa, and a curing time of 90 seconds. Immediately after molding, the high-temperature hardness (Shore D) of the test piece was measured by using a Shore D type hardness meter. The results are shown in Tables 3 and 4.

### (Evaluation of Bending Strength)

The resin compositions for molding of Example 6 and Comparative Example 4 were molded by using a transfer molding machine under the conditions of a molding temperature of 175° C., a molding pressure of 6.9 MPa, and a curing time of 120 seconds to obtain plate-shaped molded products (127 mm in length, 12.7 mm in width, and 4 mm in thickness). The products were designated as test pieces 1. Subsequently, the test pieces 1 were post-cured at 175° C. for 5 hours to obtain plate-shaped cured products (127 mm in length, 12.7 mm in width, and 4 mm in thickness). The products were designated as test pieces 2.

The bending strengths (MPa) of the test pieces 1 and 2 were measured by using Autograph (bending test machine AG-500 manufactured by Shimadzu Corporation). The results are shown in Table 4.

### (Measurement of Relative Dielectric Constant and Dielectric Loss Tangent)

The resin compositions for molding of Example 6 and Comparative Example 4 were loaded into a transfer molding machine and molded under the conditions of a mold temperature of 180° C., a molding pressure of 6.9 MPa, and a curing time of 120 seconds, followed by post-curing at 175° C. for 6 hours to prepare rectangular parallelepiped-shaped test pieces measuring 90 mm×0.6 mm×0.8 mm.

The relative dielectric constants (Dk) and dielectric loss tangents (Df) of the test pieces were measured at a frequency of 5 GHz by using a cavity resonator (Kanto Electronic Applied Development Co., Ltd.) and a network analyzer (Keysight Technologies, product name “PNA E8364B”) under an environment of 25+3° C. The results are shown in Table 4.

### (Evaluation of Release Properties)

The resin compositions for molding were compression-molded into a circular disk shape on a ferro plate (35 mm×50 mm×0.5 mm) with hard chrome plating on the surface to create cured products with circular disk areas of 3.14 cm². The molding of the resin compositions for molding was performed at a molding temperature of 175° C., a molding time of 90 seconds, and a molding pressure of 10 MPa.

Subsequently, the cured products were fixed by using a surface adsorption machine, and the ferro plate was pulled out horizontally against the interface between the cured products and the ferro plate, thereby peeling the cured products off the ferro plate. The shear release force (shear release strength) required to peel the cured product off the ferro plate was read by using a push-pull gauge (manufactured by Imada Co., Ltd., maximum scale 500 (N)).

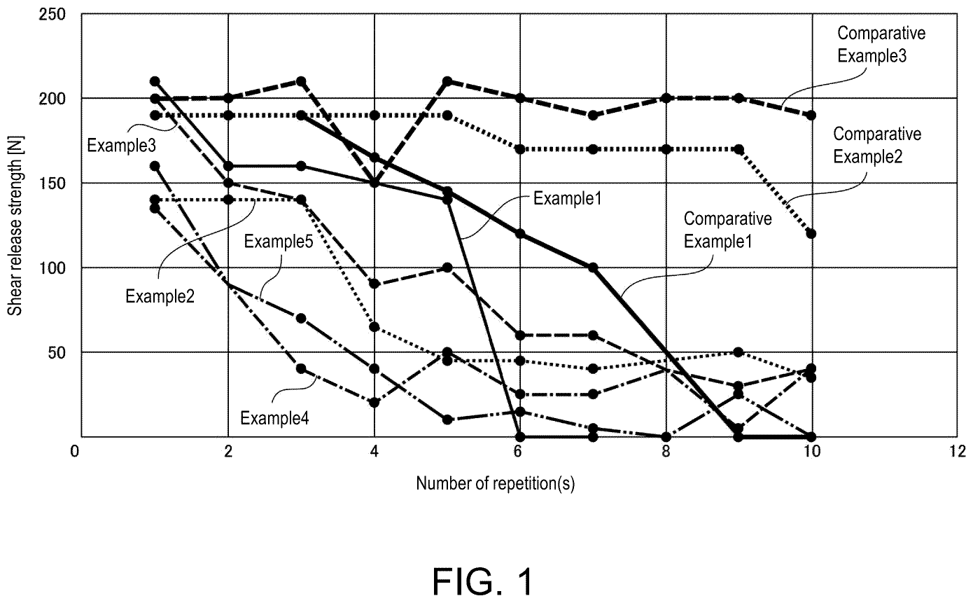

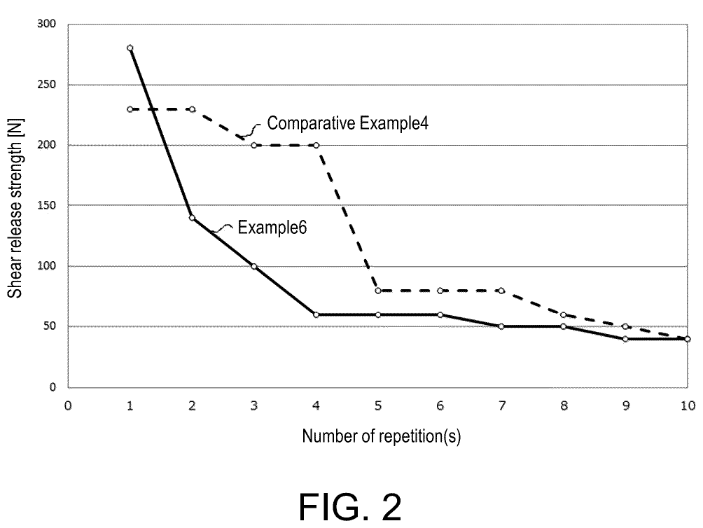

Compression-molding the resin composition for molding into a circular disk shape again at the portion where the cured product was peeled off from the ferro plate after the shear release force measurement was completed and then measuring the shear release force was repeated a total of 10 times. The measurement results are shown in Tables 3 and 4. In addition, the transition of the shear release strength at each measurement is shown in FIGS. 1 and 2. In FIG. 2, the solid line indicates the results of Example 6, and the dotted line indicates the results of Comparative Example 4.

TABLE 1

| | Example | Example | Example | Example | Example | Comparative | Comparative | Comparative |
|---|---|---|---|---|---|---|---|---|
| | 1 | 2 | 3 | 4 | 5 | Example 1 | Example 2 | Example 3 |
| Epoxy resin 1 | | | 45 | | | | | |
| Epoxy resin 2 | 30 | 30 | 25 | 30 | 30 | | | |
| Epoxy resin 3 | 70 | 70 | | 70 | 70 | 70 | 75 | 75 |
| Epoxy resin 4 | | | 30 | | | | | |
| Epoxy resin 5 | | | | | | 30 | 25 | 25 |
| Curing agent 1 | 42.2 | 42.2 | 22.3 | 34.6 | 31.6 | 36.6 | 50.7 | 50.7 |
| Curing agent 2 | | | 5.98 | 6 | 6 | | | |
| Curing agent 3 | 20.2 | 20.2 | 42.7 | 24.8 | 30.4 | 37.7 | 10.8 | 10.8 |
| Curing accelerator | 4 | 4 | 1.8 | 3.3 | 4 | 3.6 | 3.4 | 3.4 |
| Coupling agent 1 | 4.5 | 4.5 | | 4.5 | 4.5 | 3 | | |
| Coupling agent 2 | 6.8 | 6.8 | 4.5 | 6.8 | 6.8 | 6.8 | 6.8 | 6.8 |
| Coupling agent 3 | | | | | | | 4.5 | 4.5 |
| Release agent 1 | 1 | 1 | 1 | 1 | 1 | 1 | 1 | 1 |
| Release agent 2 | 1.5 | 1.5 | 1.3 | 1.5 | 1.5 | 3 | | |
| Release agent 3 | 1.5 | 1.5 | 1.3 | 1.5 | 1.5 | | 1.5 | 1.5 |
| Release agent 4 | | | | | | | 1 | 1 |
| Specific copolymer | 0.75 | 0.75 | 0.6 | 0.75 | 0.75 | 1.5 | 0.5 | 0.5 |
| Colorant | 3.5 | 3.5 | 2.6 | 3.5 | 3.5 | 3.5 | 5.2 | 5.2 |
| Additive 1 | 3 | 3 | | | | 1.5 | 1 | 1 |
| Additive 2 | 10 | 10 | | 12.5 | 15 | 10 | 5 | 5 |
| Additive 3 | 10 | 10 | 30 | 40 | 40 | | 8 | 8 |
| Filler amount | 82 | 82 | 79 | 81 | 81 | 82 | 82 | 82 |
| (volume %) | | | | | | | | |
| Inorganic filler 1 | 178 | 178 | 145 | 196 | 201 | 182 | 105 | 105 |
| Inorganic filler 2 | | | 93 | | | | | |
| Inorganic filler 3 | | | 1315 | | | | | |
| Inorganic filler 4 | 730 | 730 | | | | 1091 | | 1398 |
| Inorganic filler 5 | 365 | 365 | | | | | | |
| Inorganic filler 6 | 183 | 183 | | | | | | |
| Inorganic filler 7 | 365 | 365 | | | | | | |
| Inorganic filler 8 | 5 | 5 | | | | | | |
| Inorganic filler 9 | | | | 1767 | 1809 | 546 | | |
| Inorganic filler 10 | | | | | | | 70 | 70 |
| Inorganic filler 11 | | | | | | | 1573 | |
| Inorganic filler 12 | | | | | | | | 175 |
| Total | 2034.95 | 2034.95 | 1767.08 | 2203.75 | 2256.55 | 2027.2 | 1947.4 | 1947.4 |

TABLE 2

| | Comparative | |
|---|---|---|
| | Example 4 | Example 6 |
| Epoxy resin 6 | 75 | 75 |
| Epoxy resin 2 | | 25 |
| Epoxy resin 5 | 25 | |
| Curing agent 4 | 108 | 102 |
| Curing accelerator | 3.5 | 3.5 |
| Coupling agent 2 | 5 | 5 |
| Coupling agent 4 | 1 | 1 |
| Colorant | 2.6 | 2.6 |
| Release agent 5 | 2.5 | 2.5 |
| Specific copolymer | 0.3 | 0.6 |
| Filler amount (volume %) | 72 | 72 |
| Inorganic filler 13 | 878 | 856 |
| Inorganic filler 14 | 220 | 214 |
| Total | 1320.6 | 1286.6 |

TABLE 3

| | Example | Example | Example | Example | Example | Comparative | Comparative | Comparative |
|---|---|---|---|---|---|---|---|---|
| | 1 | 2 | 3 | 4 | 5 | Example 1 | Example 2 | Example 3 |
| GT (sec.) | 47 | 49 | 40 | 66 | 64 | 58 | 40 | 42 |
| SF (inch) | 66.2 | 67.1 | 29.4 | 61.7 | 52.2 | 71.1 | 55.2 | 54.3 |
| High-temperature | 83 | 83 | 86 | 79 | 83 | 86 | 88 | 89 |
| hardness | | | | | | | | |
| Shear release strength | | | | | | | | |
| [N] | | | | | | | | |
| First time | 210 | 140 | 200 | 135 | 160 | 190 | 190 | 200 |
| Second time | 160 | 140 | 150 | 90 | 90 | 190 | 190 | 200 |
| Third time | 160 | 140 | 140 | 40 | 70 | 190 | 190 | 210 |
| Fourth time | 150 | 65 | 90 | 20 | 40 | 165 | 190 | 150 |
| Fifth time | 140 | 45 | 100 | 50 | 10 | 145 | 190 | 210 |
| Sixth time | 0 | 45 | 60 | 25 | 15 | 120 | 170 | 200 |
| Seventh time | 0 | 40 | 60 | 25 | 5 | 100 | 170 | 190 |
| Eighth time | 0 | 45 | 40 | 40 | 0 | 50 | 170 | 200 |
| Ninth time | 0 | 50 | 30 | 5 | 25 | 0 | 170 | 200 |
| Tenth time | 0 | 35 | 40 | 40 | 0 | 0 | 120 | 190 |

TABLE 4

| | Comparative | |
|---|---|---|
| | Example 4 | Example 6 |
| GT (sec.) | 48 | 51 |
| SF (inch) | 55.9 | 49.2 |
| High-temperature hardness | 80 | 81 |
| Bending strength (test piece 1, Mpa) | 105 | 116 |
| Bending strength (test piece 2, Mpa) | 130 | 135 |
| Dk | 3.46 | 3.48 |
| Df | 0.0025 | 0.0024 |
| Shear release strength [N] | | |
| First time | 230 | 280 |
| Second time | 230 | 140 |
| Third time | 200 | 100 |
| Fourth time | 200 | 60 |
| Fifth time | 80 | 60 |
| Sixth time | 80 | 60 |
| Seventh time | 80 | 50 |
| Eighth time | 60 | 50 |
| Ninth time | 50 | 40 |
| Tenth time | 40 | 40 |

As is evident from the evaluation results in Table 3, Examples 1 to 5 using a phenol curing agent show a more rapid decrease in shear release strength than Comparative Examples 1 to 3, indicating superior release properties.

As is evident from the evaluation results in Table 4, Example 6 using an active ester compound as the curing agent shows a more rapid decrease in shear release strength than Comparative Example 4, indicating superior release properties.

The disclosure of Japanese Patent Application No. 2022-186879, filed on Nov. 22, 2022, is incorporated herein by reference in its entirety.

All the literature, patent applications, and technical standards described in the specification are incorporated herein by reference to the same extent as if each individual literature, patent application, and technical standard was specifically and individually indicated to be incorporated by reference.

1. A resin composition for molding, comprising: a sulfur atom-containing epoxy resin; a curing agent; a release agent; an inorganic filler; and a copolymer of an α-olefin having 5 to 30 carbon atoms and at least one of maleic anhydride and a maleic anhydride derivative.

2. The resin composition for molding as claimed in claim 1, wherein the sulfur atom-containing epoxy resin comprises a compound represented by General Formula (B) represented as follows: 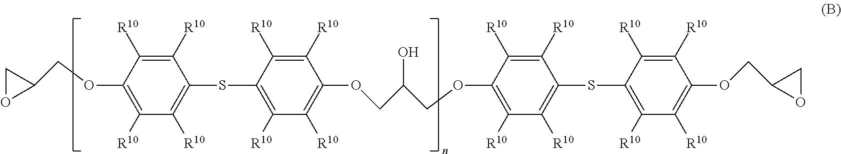
wherein in General Formula (B), R¹⁰ represents a hydrogen atom or a monovalent organic group having 1 to 18 carbon atoms, and respective R¹⁰ are all same or different, and n represents an average value and is a number from 0 to 10.

3. The resin composition for molding as claimed in claim 1, wherein the release agent is a polyethylene oxide.

4. The resin composition for molding as claimed in claim 3, wherein the polyethylene oxide is a linear polyethylene oxide.

5. The resin composition for molding as claimed in claim 3, wherein the polyethylene oxide is a branched polyethylene oxide.

6. The resin composition for molding as claimed in claim 3, wherein a weight average molecular weight of the polyethylene oxide is 2800 or more.

7. The resin composition for molding as claimed in claim 3, wherein an acid value of the polyethylene oxide is 2 mgKOH/g to 50 mgKOH/g.

8. The resin composition for molding as claimed in claim 1, wherein the copolymer comprises a structural unit represented by General Formula (C) as follows and a structural unit represented by General Formula (D) as follows: 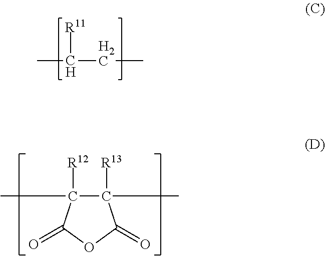
wherein in General Formula (C) and General Formula (D), R¹¹ represents a monovalent aliphatic hydrocarbon group having 3 to 28 carbon atoms, and R¹² and R¹³ each independently represent a hydrogen atom, an alkyl group, or an aryl group.

9. An electronic component device comprises: a support member; an electronic component disposed on the support member; and a cured product of the resin composition for molding as claimed in claim 1 that seals the electronic component.
